(19) United States
(12) Patent Application Publication
(10) Pub. No.: US 2003/0150382 A1
(43) Pub. Date: Aug. 14, 2003

(54) DEVICE FOR FABRICATING ALIGNMENT LAYER

(76) Inventors: Han-Chung Lai, Taoyuan Hsien (TW); Ko-Shun Wang, Taipei (TW); Bing-Chian Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,497

(22) Filed: Jan. 24, 2003

(30) Foreign Application Priority Data
Feb. 8, 2002 (TW) 91102343

(51) Int. Cl. C23C 16/00

(52) U.S. Cl. 118/718

(57) ABSTRACT

A device for fabricating an alignment layer includes a chamber, a conveying means, deposition device, and an ion beam alignment device. The conveying means is arranged in the chamber and serves to carry the substrate. The deposition device is arranged above the conveying means in the chamber and serves to form the layer. The ion beam alignment device is arranged above the conveying means in the chamber, and serves to perform the alignment of the layer. The deposition device and the ion beam alignment device can be replaced with an ion beam deposition/alignment device so that the formation and alignment of the layer can be performed in a chamber.

### CROSS REFERENCE TO RELATED APPLICATIONS

This application claims the priority benefit of Taiwan application serial no. 91102343, filed Feb. 8, 2002.

### BACKGROUND OF INVENTION

1. Field of the Invention

The present invention relates to a device for fabricating an alignment layer. More specifically, the present invention relates to a fabrication device which performs deposition and alignment of a layer in a chamber.

2. Description of the Related Art

Cathode ray tube (CRT) has been widely used as a main part of a display device because of its superior display quality and economic effect. However, in view of energy saving and compactness, there is a need for a display device which has high image quality, compactness, low energy consumption and no radiation. Liquid crystal display (LCD) has been developed and is increasingly becoming mainstream for the display products.

In current display devices, the display panel consists of two substrates and a liquid crystal layer between the substrates. In an active array LCD and a passive array LCD, each of the substrates must be provided with an alignment layer. The alignment layer twists the liquid crystal molecules in the liquid crystal layer. One conventional method of forming an alignment layer includes forming a layer by printing, and aligning the layer. The alignment layer is usually formed of polyimide. The polyimide is applied onto the substrate by printing and then rubbed in a certain direction. Alternatively, the alignment layer can be obtained by forming a layer and then ion bombarding or atom bombarding the layer at a certain tilt angle. The layer can be formed by depositing hydrogenated diamond like carbon (DLC), silicon carbide, silicon oxide, silicon nitride, or aluminum oxide.

In the prior art, polyimide printing and rubbing are performed in two separate devices. Furthermore, depositing the layer and aligning the layer are also performed in different chambers. In either of the above conventional methods, there is risk of layer pollution between two separate steps. The throughput in the prior art may be poor as well.

### SUMMARY OF INVENTION

It is an object of the present invention to provide a device for fabricating an alignment layer. The device has improved throughput and effectively prevents the alignment layer from being polluted.

In one aspect of the present invention, a device for fabricating an alignment layer including a chamber, a conveying means, deposition device and an ion beam alignment device is provided. The conveying means is arranged in the chamber and serves to carry the substrate. The deposition device is arranged above the conveying means in the chamber and serves to form a layer. The ion beam alignment device is arranged above the conveying means in the chamber, and serves to perform the alignment of the layer.

In another aspect of the present invention, a device for fabricating an alignment layer including a chamber, a conveying means, and an ion beam deposition/alignment device is provided. The conveying means is arranged in the chamber and serves to carry the substrate. The ion beam deposition/alignment device serves to form and align a layer.

In the device for fabricating the alignment layer of the invention, the conveying means includes a conveyor and a base. The base is used to carry the substrate. The conveyor is arranged under the base and serves to linearly move or horizontally rotate the base. Alternatively, the conveying means can linearly move and horizontally rotate the substrate.

The deposition device can be a physical vapor deposition device or a chemical vapor deposition device. The physical vapor deposition device can be an ion beam deposition device.

The device for fabricating the alignment layer can be further provided with a vacuum pump. The vacuum pump can be connected to the chamber.

### BRIEF DESCRIPTION OF DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic view of a device for fabricating an alignment layer according to a first preferred embodiment of the present invention;

FIG. 2 is a schematic view of a rotatable conveying means according to the first preferred embodiment of the present invention;

FIG. 3 is a schematic view showing the formation of the layer on the substrate by using the position device according to the first preferred embodiment of the present invention;

FIG. 4 is a schematic view showing the alignment of the layer by using the ion beam alignment device according to the first preferred embodiment of the present invention; and

FIG. 5 is a schematic view of a device for fabricating an alignment layer according to a second preferred embodiment of the present invention.

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts.

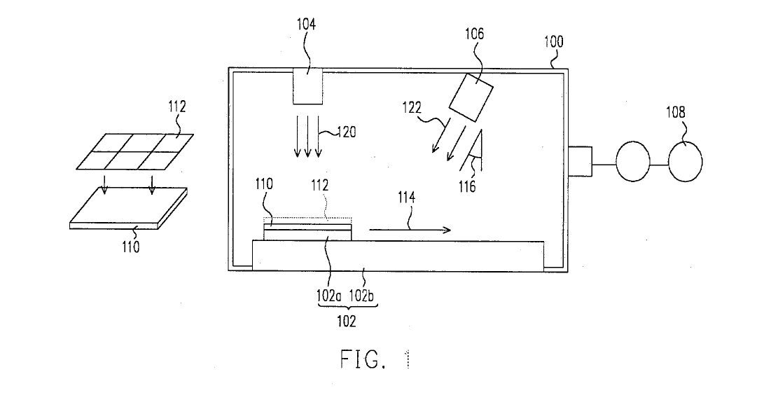

FIG. 1 is a schematic view of a device for fabricating an alignment layer according to a first preferred embodiment of the present invention. The device for fabricating the alignment layer includes a chamber 100, a conveying means 102, a deposition device 104, and an ion beam alignment device 106. The conveying means 102 is arranged in the chamber 100, for example, and serves to carry a substrate 110. The conveying means 102 includes a base 102a and a conveyor 102b. The deposition device 104 is arranged above the conveyor 102 in the chamber 100, for example, and serves to form a layer. The ion beam alignment device 106 is also located above the conveying means 102 in the chamber 100 for aligning the layer formed by the deposition device 104. The device for fabricating the alignment layer can be further provided with the vacuum pump 108. The vacuum pump 108 can be connected to the chamber 100 to keep the desired pressure for the chamber 100.

In FIG. 1, before the layer is aligned, a shadow mask 112 is arranged on the substrate 110 to ensure that the alignment layer is formed precisely on the substrate 110. Forming the alignment layer includes formation of a layer and alignment of the layer. The conveyor 102b moves the base 102a under the deposition device 104. The deposition device 104 that generates particles 120 can be a PVD device or a CVD device. One example of the PVD device is an ion beam deposition device.

After the layer is formed on the substrate 100, the conveyor 102b moves the base 102a along the direction 114 to a proper location. The ion beam 122 generated from the ion beam alignment device 106 aligns the layer. The ion beam 122 generated from the ion beam alignment device 106 has a tilt angle with respect to the substrate 110. The tilt angle is in the range of 0 to 80 degrees. In this embodiment, the ion beam 122 bombards the layer on the substrate 110 with the tilt angle 116, and then the alignment layer of the invention is accomplished. It is noted that the tilt angle 116 can be varied based on the material of the layer formed.

In FIG. 1, the base 102a serves to carry the substrate 110, and the conveyor 102b arranged under the base 102a serves to move the base 102a along the direction 114 or rotate the base 102a in a plane. Alternatively, the conveyor 102b is arranged such that the base 102a is moved along the direction 114 and rotated in a plane at the same time. With the use of the conveying means 102, the layer can be aligned in different directions.

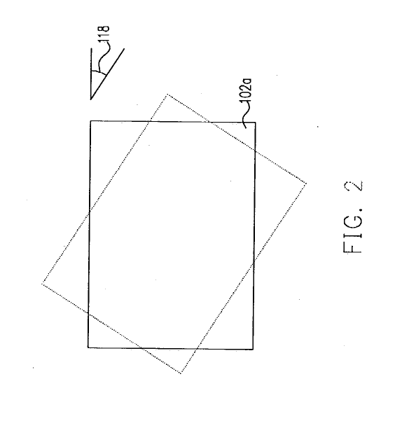

FIG. 2 is a schematic view of a rotatable conveying means according to the first preferred embodiment of the present invention. The alignment layer can be aligned in a different direction on the substrate 110 in a different type of LCD. In the invention, the alignment layer aligned in a varied alignment direction can be obtained by adjusting a rotation angle 118 of the base 102a in a horizontal direction. In other words, the horizontal rotation of the base 102a determines the alignment direction of the alignment layer.

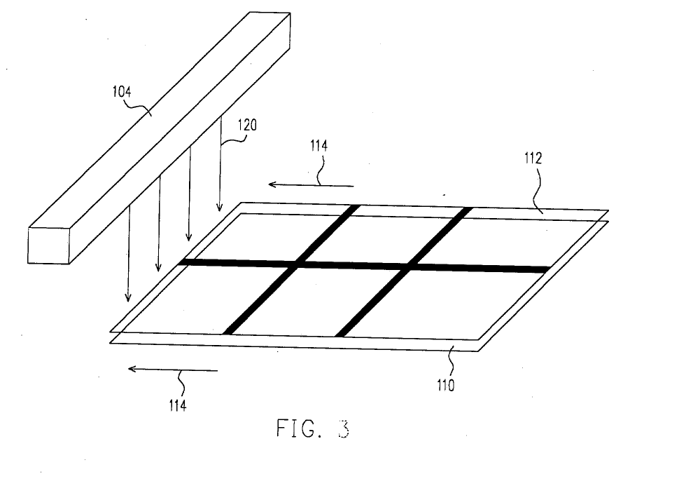

FIG. 3 is a schematic view showing the formation of the layer on the substrate by using the position device according to the first preferred embodiment of the present invention. Before the layer is formed, the shadow mask 112 is placed on the substrate, and then the substrate 110 is put on the conveying means 102 (not shown). The conveying means 102 moves the substrate 110 along the direction 114. The particles 120 generated from the deposition device 104 form a layer on the substrate 110.

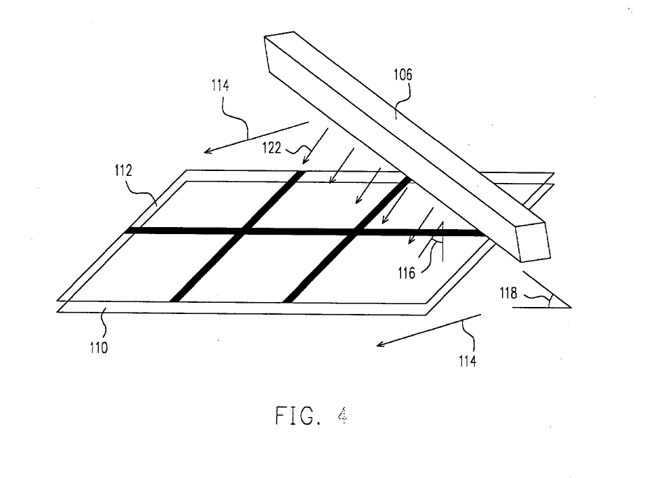

FIG. 4 is a schematic view showing the alignment of the layer by using the ion beam alignment device according to the first preferred embodiment of the present invention. After the layer is formed, the conveying means 102 (not shown) horizontally rotates the substrate 110 with an angle 118, while linearly moving the substrate and the shadow mask 112 thereon along the direction 114. While the substrate 110 is moved, the ion beam 122 generated from the ion beam alignment device 106 with a tilt angle 116 is used to perform alignment of the layer.

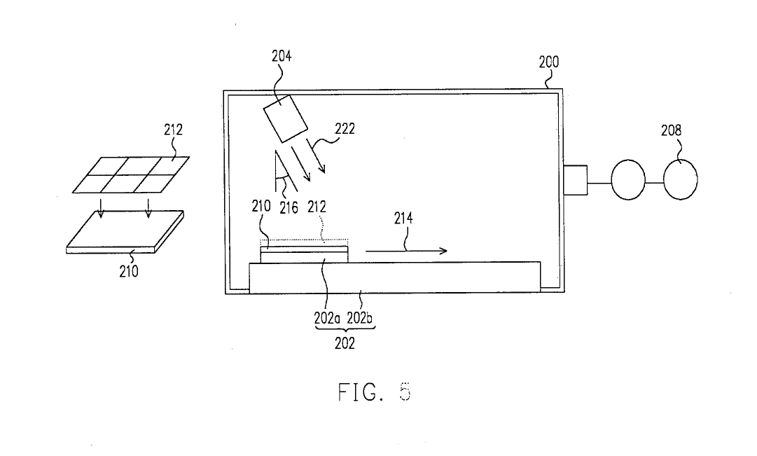

FIG. 5 is a schematic view of a device for fabricating an alignment layer according to a second preferred embodiment of the present invention. The device for fabricating the alignment layer includes a chamber 200, a conveying means 202, and an ion beam deposition/alignment device 204. The conveying means 202 is arranged in the chamber 200, for example, and serves to carry a substrate 210. The deposition device 204 is arranged above the conveyor 202 in the chamber 200, for example, and serves to form and align a layer. The device for fabricating the alignment layer can be further provided with the vacuum pump 208. The vacuum pump 208 can be connected to the chamber 200 to keep the desired pressure for the chamber 200.

The device for fabricating the alignment layer in this embodiment is the same as that in the first embodiment except that the deposition device 104 and the ion beam alignment device 106 shown in Fig.1 are replaced with the ion beam deposition/alignment device 204.

In a view of foregoing, the device for fabricating the alignment layer according to the present invention has the following advantages over the prior art:

1. Formation and alignment of the layer can be performed in the same chamber.

2. The conveying means can linearly move and horizontally rotate the substrate in order to easily align the layer on the substrate.

3. The ion beam deposition/alignment device can perform both layer formation and layer alignment. Therefore, the device for fabricating the alignment layer can be compact.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A device for fabricating an alignment layer, which can form a layer on a substrate and align the layer, the device comprising:
a chamber;
a conveying means arranged in the chamber, wherein the conveying means carries the substrate;
a deposition device arranged above the conveying means in the chamber, wherein the deposition device serves to form the layer; and
an ion beam alignment device arranged above the conveying means in the chamber, wherein the ion beam alignment device serves to perform the alignment of the layer.

2. The device of claim 1, wherein the conveying means comprising:
a base used to carry the substrate; and
a conveyor arranged under the base to linearly move the base.

3. The device of claim 1, wherein the conveying means comprising:
a base used to carry the substrate; and
a conveyor arranged under the base to horizontally rotate the base.

4. The device of claim 1, wherein the conveying means comprising:
a base used to carry the substrate; and
a conveyor arranged under the base to linearly move and horizontally rotate the base.

5. The device of claim 1, wherein the deposition device comprises a physical vapor deposition (PVD) device.

6. The device of claim 1, wherein the PVD device comprises an ion beam deposition device.

7. The device of claim 1, wherein the deposition device comprises a chemical vapor deposition (CVD) device.

8. The device of claim 1, further comprising a vacuum pump connected to the chamber.

9. A device for fabricating an alignment layer, which can form a layer on a substrate and align the layer, the device comprising:
a chamber;
a conveying means arranged in the chamber, wherein the conveying means carries the substrate; and
an ion beam deposition/alignment device arranged above the conveying means in the chamber, wherein the deposition device serves to form and align the layer.

10. The device of claim 9, wherein the conveying means comprising:
a base used to carry the substrate; and
a conveyor arranged under the base to linearly move the base.

11. The device of claim 9, wherein the conveying means comprising:
a base used to carry the substrate; and
a conveyor arranged under the base to horizontally rotate the base.

12. The device of claim 9, wherein the conveying means comprising:
a base used to carry the substrate; and
a conveyor arranged under the base to linearly move and horizontally rotate the base.

13. The device of claim 9, further comprising a vacuum pump connected to the chamber.
